(19) United States
(12) Patent Application Publication
(10) Pub. No.: US 2026/0271324 A1
(43) Pub. Date: Sep. 10, 2026

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Jiangsu (CN)

(72) Inventors: Jun TANG, Jiangsu (CN); Han-Chin CHIU, Jiangsu (CN)

(73) Assignee: INNOSCIENCE (SUZHOU) SEMICONDUCTOR CO., LTD., Jiangsu (CN)

(21) Appl. No.: 18/876,193

(22) PCT Filed: Jun. 24, 2022
(86) PCT No.: PCT/CN2022/101267

§ 371 Date: Dec. 18, 2024

(51) Int. Cl. H10D 30/47; H10D 30/01; H10D 62/85; H10D 64/01; H10D 64/64; H10W 74/10

(52) U.S. Cl. CPC H10D 30/475; H10D 30/015; H10D 62/8503; H10D 64/0124; H10D 64/64; H10W 74/137

(57) ABSTRACT

A nitride-based semiconductor device includes a first nitride-based semiconductor layer, a second nitride-based semiconductor layer, a doped nitride-based semiconductor layer, a third nitride-based semiconductor layer, and a fourth nitride-based semiconductor layer. The second nitride-based semiconductor layer is disposed on the first nitride-based semiconductor layer. The second nitride-based semiconductor layer has a bandgap higher than a bandgap of the first nitride-based semiconductor layer. The doped nitride-based semiconductor layer is disposed over the second nitride-based semiconductor. The third nitride-based semiconductor layer is disposed on the doped nitride-based semiconductor layer and is narrower than the doped nitride-based semiconductor layer. The fourth nitride-based semiconductor layer is disposed on the third nitride-based semiconductor layer and is narrower than the doped nitride-based semiconductor layer. The third and fourth nitride-based semiconductor layers have the same composition and different physical characteristics.

### FIELD OF THE DISCLOSURE

The present disclosure generally relates to a nitride-based semiconductor device. More specifically, the present disclosure relates to a nitride-based semiconductor device having a hydrogen barrier layer to keep P-GaN away from hydrogen diffusion.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a nitride-based semiconductor device is provided. A nitride-based semiconductor device includes a first nitride-based semiconductor layer, a second nitride-based semiconductor layer, a doped nitride-based semiconductor layer, a third nitride-based semiconductor layer, and a fourth nitride-based semiconductor layer. The second nitride-based semiconductor layer is disposed on the first nitride-based semiconductor layer. The second nitride-based semiconductor layer has a bandgap higher than a bandgap of the first nitride-based semiconductor layer. The doped nitride-based semiconductor layer is disposed over the second nitride-based semiconductor. The third nitride-based semiconductor layer is disposed on the doped nitride-based semiconductor layer and is narrower than the doped nitride-based semiconductor layer. The fourth nitride-based semiconductor layer is disposed on the third nitride-based semiconductor layer and is narrower than the doped nitride-based semiconductor layer. The third and fourth nitride-based semiconductor layers have the same composition and different physical characteristics.

In accordance with one aspect of the present disclosure, a method for manufacturing a semiconductor device is provided. The method includes steps as follows. A first nitride-based semiconductor layer is formed. A second nitride-based semiconductor layer is formed on the first nitride-based semiconductor layer. A doped nitride-based semiconductor layer is formed over the second nitride-based semiconductor layer. A third nitride-based semiconductor layer is formed on the doped nitride-based semiconductor layer. A fourth nitride-based semiconductor layer is formed on the third nitride-based semiconductor layer. The third and fourth nitride-based semiconductor layers have the same composition and different physical characteristics.

In accordance with one aspect of the present disclosure, a nitride-based semiconductor device is provided. A III-nitride-based semiconductor device includes a first nitride-based semiconductor layer, a second nitride-based semiconductor layer, a doped nitride-based semiconductor layer, a third nitride-based semiconductor layer, and a fourth nitride-based semiconductor layer. The second nitride-based semiconductor layer is disposed on the first nitride-based semiconductor layer. The second nitride-based semiconductor layer has a bandgap higher than a bandgap of the first nitride-based semiconductor layer. The doped nitride-based semiconductor layer is disposed over the second nitride-based semiconductor. The third nitride-based semiconductor layer is disposed on the doped nitride-based semiconductor layer and is narrower than the doped nitride-based semiconductor layer. The fourth nitride-based semiconductor layer is disposed on the third nitride-based semiconductor layer and is narrower than the doped nitride-based semiconductor layer. The third and fourth nitride-based semiconductor layers have the same composition and different physical characteristics, and the third nitride-based semiconductor layer is thinner than the fourth nitride-based semiconductor layer.

By applying the above configuration, once hydrogen diffusion occurs, at least one hydrogen element may be present within the fourth nitride-based semiconductor layer but the hydrogen is blocked by the third nitride-based semiconductor layer. As such, hydrogen diffusion to the doped III-V semiconductor layer is avoided.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical cross-sectional view of a nitride-based semiconductor device according to some embodiments of the present disclosure;

FIG. 1B is an enlargement view of a region in FIG. 1A;

FIG. 2A, FIG. 2B, FIG. 2C, FIG. 2D, FIG. 2E, FIG. 2F, FIG. 2G, and FIG. 2H show different stages of a method for manufacturing the nitride-based semiconductor device according to some embodiments of the present disclosure;

FIG. 3 is a vertical cross-sectional view of a semiconductor device according to some embodiments of the present disclosure;

FIG. 4 is a vertical cross-sectional view of a semiconductor device according to some embodiments of the present disclosure; and

FIG. 5 is a vertical cross-sectional view of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

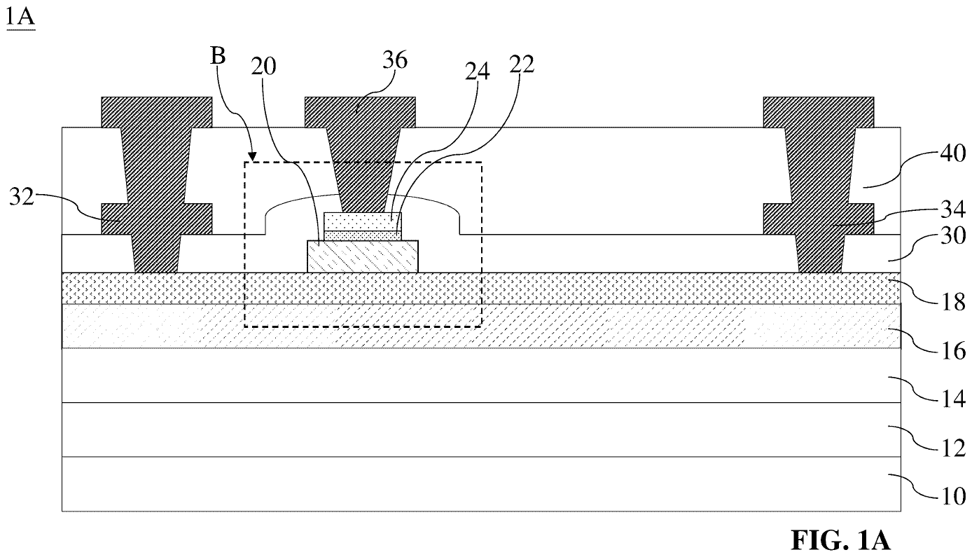

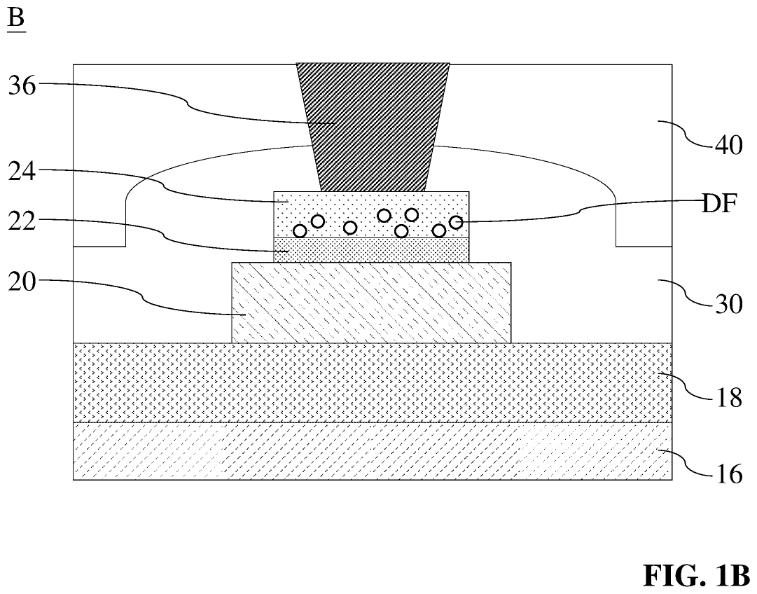

FIG. 1A is a vertical cross-sectional view of a nitride-based semiconductor device 1A according to some embodiments of the present disclosure. The semiconductor device 1A includes a substrate 10, a buffer layer 12, an electron blocking layer 14, nitride-based semiconductor layers 16 and 18, a doped III-V semiconductor layer 20, nitride-based semiconductor layers 22 and 24, passivation layers 30 and 40, electrodes 32, 34, 36.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The buffer layer 12 can be disposed between the substrate 10 and the electron blocking layer 14. The buffer layer 12 can be configured to reduce lattice and thermal mismatches between the substrate 10 and the electron blocking layer 14, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the nitride-based semiconductor device 1A further includes a nucleation layer (not illustrated). The nucleation layer may be formed between the substrate 10 and the buffer layer 12. The nucleation layer can be configured to provide a transition to accommodate a mismatch/difference between the substrate 10 and a III-nitride layer of the buffer layer. The exemplary material of the nucleation layer can include, for example but is not limited to AIN or any of its alloys.

The electron blocking layer 14 can be disposed between the buffer layer 12 and the nitride-based semiconductor layer 16. The electron blocking layer 14 may include AlₓGa₍₁₋ₓ₎N, where 0≤x≤1 . In some embodiments, the electron blocking layer 14 may have a high bandgap. In some embodiments, the electron blocking layer 14 may be doped as being p-type. In some embodiments, the electron blocking layer 14 may have an AlGaN/GaN super-lattice structure, including alternating layers of AlGaN and GaN.

The nitride-based semiconductor layer 16 is disposed over the substrate 10. The nitride-based semiconductor layer 18 is disposed on the nitride-based semiconductor layer 16. The exemplary materials of the nitride-based semiconductor layer 16 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary materials of the nitride-based semiconductor layer 18 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 16 and 18 are selected such that the nitride-based semiconductor layer 18 has a bandgap (i.e., forbidden band width) greater than a bandgap of the nitride-based semiconductor layer 16, which causes electron affinities thereof different from each other and forms a heterojunction therebetween. For example, when the nitride-based semiconductor layer 16 is an undoped GaN layer having a bandgap of approximately 3.4 eV, the nitride-based semiconductor layer 18 can be selected as an AlGaN layer having bandgap of approximately 4.0 eV. As such, the nitride-based semiconductor layers 16 and 18 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The doped III-V semiconductor layer 20 is disposed on/over/above the nitride-based semiconductor layer 18. The doped III-V semiconductor layer 20 may have p-type doing. The doped III-V semiconductor layer 20 is configured to bring the device into enhancement mode. The doped III-V semiconductor layer 20 can be a p-type doped III-V semiconductor layer. The exemplary materials of the doped III-V semiconductor layer 20 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg.

The nitride-based semiconductor layers 22 and 24 are disposed on/over/above the doped III-V semiconductor layer 20. The nitride-based semiconductor layer 24 is disposed on/over/above the nitride-based semiconductor layer 22. The nitride-based semiconductor layer 22 is narrower than the doped nitride-based semiconductor layer 20. The nitride-based semiconductor layer 24 is narrower than the doped nitride-based semiconductor layer 20.

The combination of the nitride-based semiconductor layers 22 and 24 can promote contact property with respect to the doped III-V semiconductor layer 20. As such, a contact interface between the doped III-V semiconductor layer 20 and the nitride-based semiconductor layer 22 can be improved so the resistance therebetween is reduced.

The nitride-based semiconductor layer 22 can be configured to serve as a diffusion barrier layer for the doped III-V semiconductor layer 20. In this regard, the nitride-based semiconductor layers 22 and 24 have the same composition but different physical characteristics.

The reason for such the configuration is based on the consideration of the yield rate and the manufacturing cost of the semiconductor device 1A. Specifically, the nitride-based semiconductor layers 22 can be formed by a high cost and a process of high time requirement (i.e., slow growth) and thus the nitride-based semiconductor layers 22 is formed to have a desired high diffusion barrier property.

FIG. 1B is an enlargement view of a region B in FIG. 1A. The doped III-V semiconductor layer 20 is activated to become p-type doping by introducing dopants. In this mechanism, hydrogen is de-bonded from the doped III-V semiconductor layer 20 and the dopants bond in the doped III-V semiconductor layer 20 so the doped III-V semiconductor layer 20 can have p-type property.

Accordingly, after the formation of the doped III-V semiconductor layer 20, a layer to be formed on the doped III-V semiconductor layer 20 is better to provide protection of hydrogen diffusion to the doped III-V semiconductor layer 20. In this regard, a single nitride-based semiconductor layer may face an issue of “high protection but high cost” or “low cost but low protection.”

The nitride-based semiconductor layers 22 and 24 can be formed by different approaches. For example, the nitride-based semiconductor layer 22 can be formed by using atomic layer deposition (ALD) and the nitride-based semiconductor layer 24 can be formed by using physical vapor deposition (PVD). Although the different approaches are applied thereto, both the nitride-based semiconductor layers 22 and 24 are composed of titanium nitride (TiN). As such, the nitride-based semiconductor layers 22 and 24 can have different physical characteristics.

The ALD approach can make the nitride-based semiconductor layer 22 have high density such that the nitride-based semiconductor layer 22 is enough to block hydrogen diffusion DF. Since the ALD approach makes a layer growing in a slow rate, the nitride-based semiconductor layer 22 is formed in the little thickness and another approach is applied to compensate for thickness of the combination of the nitride-based semiconductor layers 22 and 24. The nitride-based semiconductor layer 24 is formed using the PVD approach to continuously grow from the nitride-based semiconductor layer 22.

By such the configuration, the nitride-based semiconductor layer 22 can have hydrogen barrier property stronger than that of the nitride-based semiconductor layer 24. Furthermore, the nitride-based semiconductor layers 22 and 24 have different densities. In some embodiments, the nitride-based semiconductor layer 22 can have the density greater than the density of the nitride-based semiconductor layer 24. In some embodiments, the nitride-based semiconductor layers 22 and 24 have different conductivities.

The nitride-based semiconductor layer 22 located between the doped III-V semiconductor layer 20 and the nitride-based semiconductor layer 24 can block element diffusion from upward to the doped III-V semiconductor layer 20. The nitride-based semiconductor layer 24 makes contact with the nitride-based semiconductor layer 22 to form a visible interface therebetween.

In some embodiments, the nitride-based semiconductor layers 22 and 24 have substantially the same width. In some embodiments, the nitride-based semiconductor layers 22 and 24 have different thicknesses. The nitride-based semiconductor layer 24 is thicker than the nitride-based semiconductor layer 22. In some embodiments, a ratio of the thickness of the nitride-based semiconductor layer 24 to the thickness of the nitride-based semiconductor layer 22 is in a range from about 15 to about 25. Such the ratio can achieve the balance based on the yield rate and the cost. In some embodiments, the nitride-based semiconductor layer 22 has a thickness in a range from about 4 nm to about 6 nm. In some embodiments, the nitride-based semiconductor layer 22 has a thickness in a range from about 80 nm to about 120 nm.

In the exemplary illustration of FIG. 1B, once hydrogen diffusion DF occurs, at least one hydrogen element may be present within the nitride-based semiconductor layer 24 but the hydrogen is blocked by the nitride-based semiconductor layer 22. As such, hydrogen diffusion DF to the doped III-V semiconductor layer 20 is avoided.

Referring back to FIG. 1A, the passivation layer 30 is disposed over the nitride-based semiconductor layer 18. The passivation layer 30 covers the doped III-V semiconductor layer 20 and the nitride-based semiconductor layers 22 and 24. The passivation layer 30 can be formed for a protection purpose or for enhancing the electrical properties of the device (e.g., by providing an electrically isolation effect between/among different layers/elements). The exemplary materials of the passivation layers 30 can include, for example but are not limited to, SiNₓ, SiOₓ, Si₃N₄, SiON, SiC, SiBN, SiCBN, oxides, nitrides, or combinations thereof. In some embodiments, the passivation layers 30 can be a multi-layered structure, such as a composite dielectric layer of Al₂O₃/SiN, Al₂O₃/SiO₂, AlN/SiN, AlN/SiO₂, or combinations thereof.

The passivation layer 40 is disposed over the passivation layer 30. The passivation layer 30 covers the passivation layer 30. The passivation layer 30 can be formed for a protection purpose or for enhancing the electrical properties of the device (e.g., by providing an electrically isolation effect between/among different layers/elements). The exemplary materials of the passivation layers 40 can include, for example but are not limited to, SiNₓ, SiOₓ, Si₃N₄, SiON, SiC, SiBN, SiCBN, oxides, nitrides, or combinations thereof. In some embodiments, the passivation layers 40 can be a multi-layered structure, such as a composite dielectric layer of Al₂O₃/SiN, Al₂O₃/SiO₂, AlN/SiN, AlN/SiO₂, or combinations thereof.

The electrodes 32 and 34 are disposed on the nitride-based semiconductor layer 18. The electrodes 32 and 34 can upward extend to a position higher than the passivation 40. Each of the electrodes 32 and 34 can serve as a source electrode or a drain electrode. Each of the electrodes 32 and 34 can serve as a source contact via or a drain contact via. The electrodes 32 and 34 can penetrate the passivation layers 30 and 40 to make contact with the nitride-based semiconductor layer 18.

In some embodiments, the electrodes 32 and 34 can include, for example but are not limited to, metals, alloys, doped semiconductor materials (such as doped crystalline silicon), compounds such as silicides and nitrides, other conductor materials, or combinations thereof. The exemplary materials of the electrodes 32 and 34 can include, for example but are not limited to, Ti, AlSi, TiN, or combinations thereof. The electrodes 32 and 34 may be a single layer, or plural layers of the same or different composition. In some embodiments, the electrodes 32 and 34 form ohmic contact with the nitride-based semiconductor layer 18. The ohmic contact can be achieved by applying Ti, Al, or other suitable materials to the electrodes 32 and 34.

In some embodiments, each of the electrodes 32 and 34 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The electrode 36 is disposed on/above/over the nitride-based semiconductor layer 18. The electrode 36 can upward extend to a position higher than the passivation 40. The electrode 36 is disposed on/above/over the doped III-V semiconductor layer 20. The electrode 36 is disposed on/above/over the nitride-based semiconductor layers 22 and 24. The electrode 36 can serve as a gate electrode. The electrode 36 can serve as a gate contact via. The electrode 36 can penetrate the passivation layers 30 and 40 to make contact with the nitride-based semiconductor layer.

The exemplary materials of the electrode 36 may include metals or metal compounds. The electrode 36 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

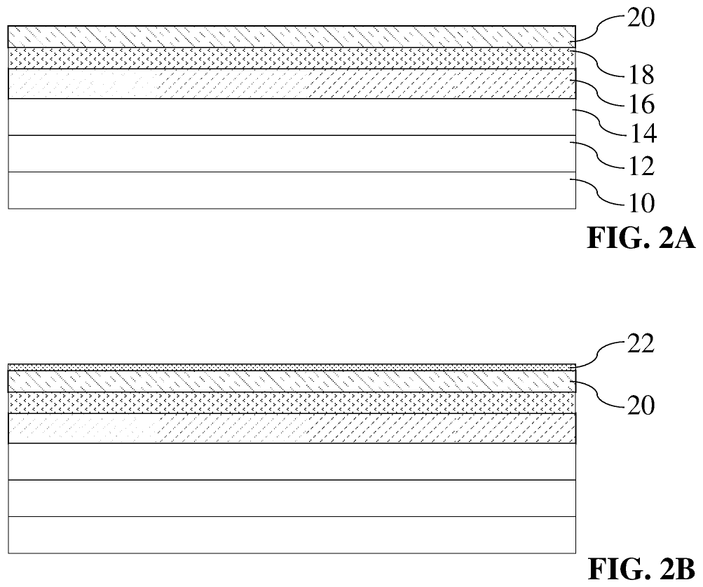

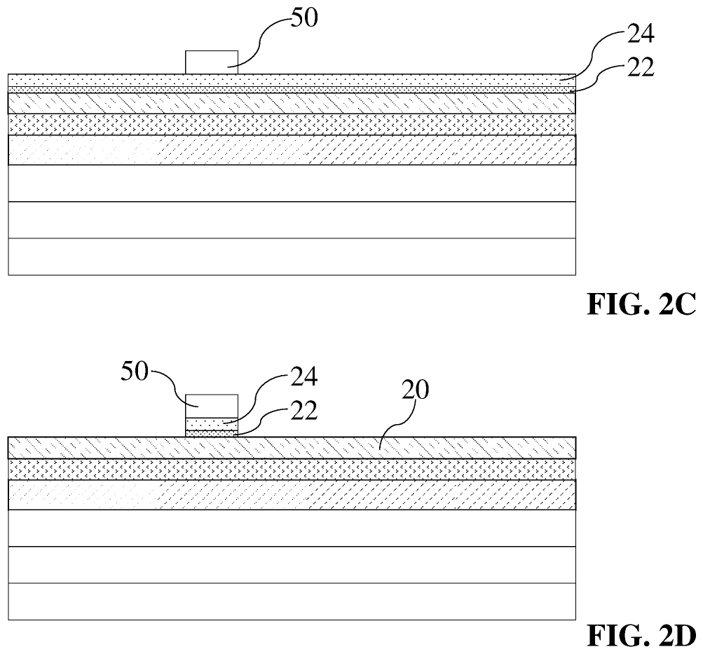

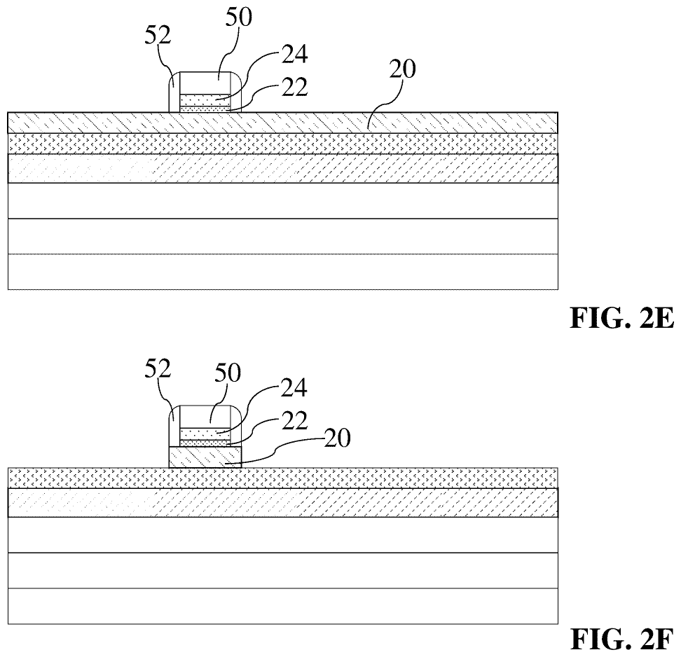

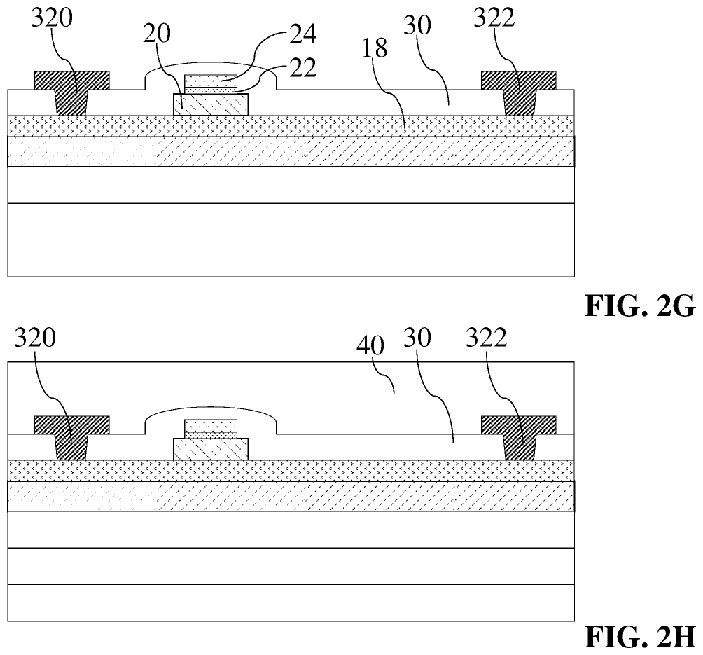

Different stages of a method for manufacturing the semiconductor device 1A are shown in FIG. 2A, FIG. 2B, FIG. 2C, FIG. 2D, FIG. 2E, FIG. 2F, FIG. 2G, and FIG. 2H, described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 10 is provided. A buffer layer 12 is formed on the substrate 10. An electron blocking layer 14 is formed on the substrate 10. Nitride-based semiconductor layers 16 and 18 are formed over the substrate 10, the buffer layer 12, and the electron blocking layer 14 in sequence. A doped III-V semiconductor layer 20 is formed over the nitride-based semiconductor layers 16 and 18.

Referring to FIG. 2B, a nitride-based semiconductor layer 22 is formed on the doped III-V semiconductor layer 20. As afore described, the nitride-based semiconductor layer 22 can be formed by applying the ALD approach. In some embodiments, an entirety of the nitride-based semiconductor layer 22 is formed in a chamber by using an ALD process.

Referring to FIG. 2C, a nitride-based semiconductor layer 24 is formed on the nitride-based semiconductor layer 22. A mask layer 50 is formed on the nitride-based semiconductor layer 24 to cover a portion of the nitride-based semiconductor layer 24. As afore described, the nitride-based semiconductor layer 24 can be formed by applying the PVD approach. In some embodiments, an entirety of the nitride-based semiconductor layer 24 is formed in a chamber by using a PVD process.

The nitride-based semiconductor layers 22 and 24 have the same composition and different physical characteristics. In some embodiments, the nitride-based semiconductor layers 22 and 24 are composed of titanium nitride (TiN). In some embodiments, the nitride-based semiconductor layers 22 and 24 are formed by using different approaches. In some embodiments, the nitride-based semiconductor layers 22 and 24 are formed in different chambers. In some embodiments, the nitride-based semiconductor layers 22 and 24 have different conductivities. In some embodiments, the nitride-based semiconductor layers 22 and 24 have different thicknesses.

Referring to FIG. 2D, a removing process is performed on the nitride-based semiconductor layers 22 and 24 by using the mask layer 50. The profile of the mask layer dominates the profile of the nitride-based semiconductor layers 22 and 24. The nitride-based semiconductor layers 22 and 24 directly beneath the mask layer 50 are remained. The removing process includes at least one etching process. After the removing process, the doped III-V semiconductor layer 20 is exposed.

Referring to FIG. 2E, spacers 52 are disposed on the doped III-V semiconductor layer 20. The nitride-based semiconductor layers 22 and 24 and the mask layer 50 are located between the spacers 52. Sidewalls of the nitride-based semiconductor layers 22 and 24 and the mask layer 50 can abut against the spacers 52.

Referring to FIG. 2F, a removing process is performed on the doped III-V semiconductor layer 20. The doped III-V semiconductor layer 20 directly beneath the mask layer 50 and the spacers 52 remain. The remained doped III-V semiconductor layer 20 is wider than the nitride-based semiconductor layers 22 and 24. The removing process includes at least one etching process. The nitride-based semiconductor layers 22 and 24 can be protected by the mask layer 50 and the spacers 52 from the removing process.

Referring to FIG. 2G, the mask layer and the spacers are removed. A passivation layer 30 is formed to cover the nitride-based semiconductor layer 18, the doped III-V semiconductor layer 20, and the nitride-based semiconductor layers 22 and 24. Bottom electrodes 320 and 322 are formed to penetrate the passivation layer 30 to make contact with the nitride-based semiconductor layer 18.

Referring to FIG. 2H, a passivation layer 30 is formed to cover the passivation layer 30 and the bottom electrodes 320 and 322. Thereafter, top electrodes can be formed to penetrate the passivation layer 40 to make contact with the bottom electrodes 320 and 322 respectively. A gate contact via can be formed to penetrate the passivation layers 30 and 40. As such, the structure as afore mentioned in FIG. 1A is obtained.

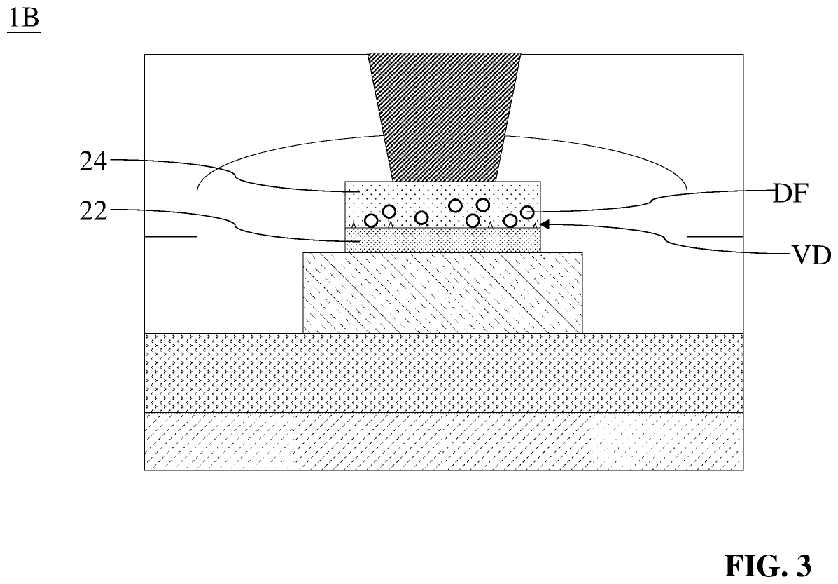

FIG. 3 is a vertical cross-sectional view of a semiconductor device 1B according to some embodiments of the present disclosure. The semiconductor device 1B is similar to the semiconductor device 1A as described and illustrated with reference to FIGS. 1A and 1B, except that at least one void VD present between the nitride-based semiconductor layers 22 and 24.

Specifically, after the nitride-based semiconductor layer 22 is formed, the structure is brought to another chamber for the formation of the nitride-based semiconductor layer 24. At this stage, by tuning recipes of the growth of the nitride-based semiconductor layer 24, the voids VD can be created at the interface between the nitride-based semiconductor layers 22 and 24. As the conductivity at the interface is acceptable, the voids VD can make hydrogen diffusion DF blocked more.

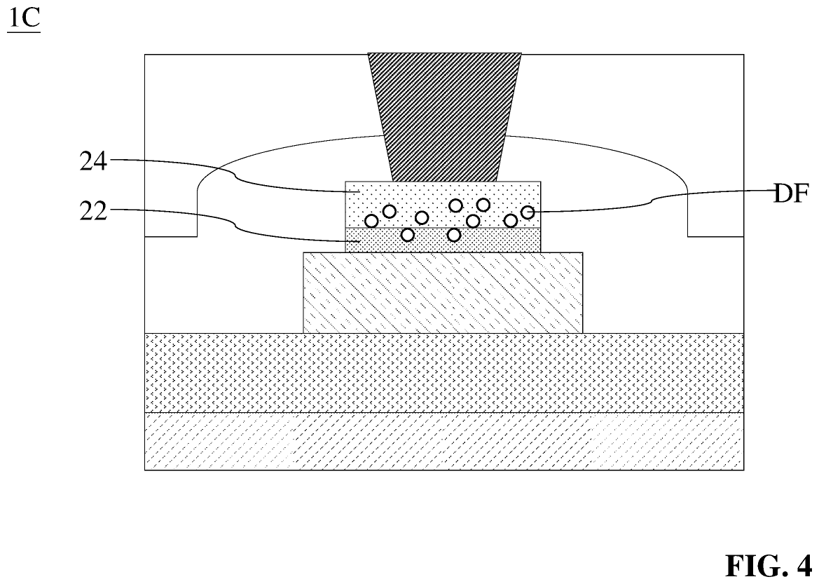

FIG. 4 is a vertical cross-sectional view of a semiconductor device 1C according to some embodiments of the present disclosure. The semiconductor device 1C is similar to the semiconductor device 1A as described and illustrated with reference to FIGS. 1A and 1B, except that hydrogen diffusion DF may occur in the nitride-based semiconductor layer 22 as well. In some embodiments, the hydrogen elements may diffuse into the nitride-based semiconductor layer 22. Since the nitride-based semiconductor layer 22 may have high density, the hydrogen diffusion DF occurring in the nitride-based semiconductor layer 22 may be slightly and it is acceptable. Such the situation may occur at a condition the formation of the nitride-based semiconductor layer 22 is speeded up.

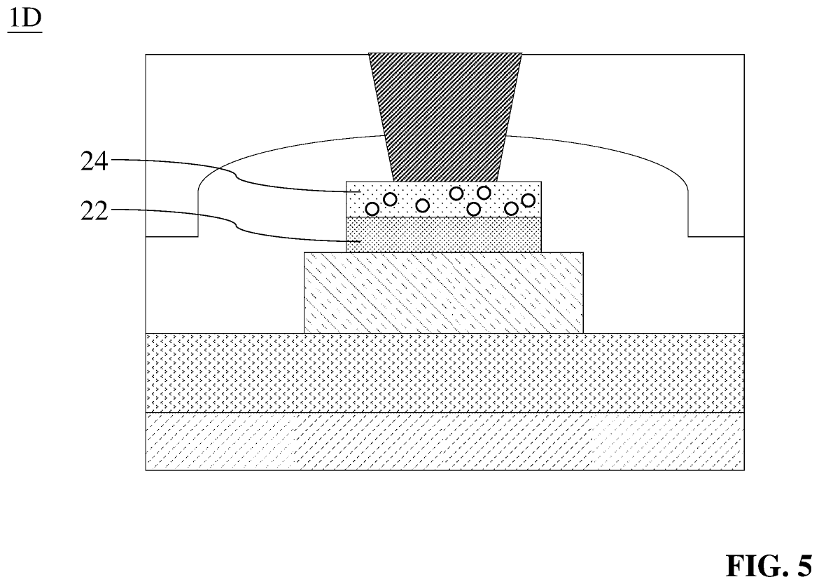

FIG. 5 is a vertical cross-sectional view of a semiconductor device 1D according to some embodiments of the present disclosure. The semiconductor device 1D is similar to the semiconductor device 1A as described and illustrated with reference to FIGS. 1A and 1B, except that the nitride-based semiconductor layers 22 and 24 have substantially the same thickness. The nitride-based semiconductor layer 22 thick the same as the nitride-based semiconductor layer 24 can provide hydrogen diffusion block more.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer, wherein the second nitride-based semiconductor layer has a bandgap higher than a bandgap of the first nitride-based semiconductor layer;
a doped nitride-based semiconductor layer disposed over the second nitride-based semiconductor;
a third nitride-based semiconductor layer disposed on the doped nitride-based semiconductor layer and narrower than the doped nitride-based semiconductor layer; and
a fourth nitride-based semiconductor layer disposed on the third nitride-based semiconductor layer and narrower than the doped nitride-based semiconductor layer, wherein the third and fourth nitride-based semiconductor layers have the same composition and different physical characteristics.

2. The semiconductor device of claim 1, wherein the third and fourth nitride-based semiconductor layers are composed of titanium nitride (TiN).

3. The semiconductor device of claim 1, wherein the third and fourth nitride-based semiconductor layers have different conductivities.

4. The semiconductor device of claim 1, wherein the third and fourth nitride-based semiconductor layers have different thicknesses.

5. The semiconductor device of claim 4, wherein the fourth nitride-based semiconductor layer is thicker than the third nitride-based semiconductor layer.

6. The semiconductor device of claim 5, wherein a ratio of the thickness of the fourth nitride-based semiconductor layer to the thickness of the third nitride-based semiconductor layer is in a range from 15 to 25.

7. The semiconductor device of claim 1, wherein the third nitride-based semiconductor layer has hydrogen barrier property stronger than that of the fourth nitride-based semiconductor layer.

8. The semiconductor device of claim 1, wherein the fourth nitride-based semiconductor layer makes contact with the third nitride-based semiconductor layer to form a visible interface therebetween.

9. The semiconductor device of claim 1, wherein the third and fourth nitride-based semiconductor layers have different densities.

10. The semiconductor device of claim 9, wherein the third nitride-based semiconductor layer has the density greater than the density of the fourth nitride-based semiconductor layer.

11. The semiconductor device of claim 1, further comprising:
a passivation layer disposed over the second nitride-based semiconductor layer and covering the third and fourth nitride-based semiconductor layers.

12. The semiconductor device of claim 11, further comprising:
a gate contact via penetrating the passivation layer to make contact with the and fourth nitride-based semiconductor layer.

13. The semiconductor device of claim 1, wherein at least one hydrogen element diffusion present in the fourth nitride-based semiconductor layer.

14. The semiconductor device of claim 1, wherein the third and fourth nitride-based semiconductor layers have substantially the same width.

15. The semiconductor device of claim 1, wherein the third nitride-based semiconductor layer has a thickness in a range from 4 nm to 6 nm.

16. A method for manufacturing a semiconductor device, comprising:
forming a first nitride-based semiconductor layer;
forming a second nitride-based semiconductor layer on the first nitride-based semiconductor layer;
forming a doped nitride-based semiconductor layer over the second nitride-based semiconductor layer;
forming a third nitride-based semiconductor layer on the doped nitride-based semiconductor layer; and
forming a fourth nitride-based semiconductor layer on the third nitride-based semiconductor layer, wherein the third and fourth nitride-based semiconductor layers have the same composition and different physical characteristics.

17. The method of claim 16, wherein the third and fourth nitride-based semiconductor layers are formed in different chambers.

18. The method of claim 16, wherein the third and fourth nitride-based semiconductor layers are composed of titanium nitride (TIN).

19. The method of claim 16, wherein the third and fourth nitride-based semiconductor layers have different conductivities.

20. (canceled)

21. A nitride-based semiconductor device, comprising:
a first nitride-based semiconductor layer;
a second nitride-based semiconductor layer disposed on the first nitride-based semiconductor layer, wherein the second nitride-based semiconductor layer has a bandgap higher than a bandgap of the first nitride-based semiconductor layer;
a doped nitride-based semiconductor layer disposed over the second nitride-based semiconductor;
a third nitride-based semiconductor layer disposed on the doped nitride-based semiconductor layer and narrower than the doped nitride-based semiconductor layer; and
a fourth nitride-based semiconductor layer disposed on the third nitride-based semiconductor layer and narrower than the doped nitride-based semiconductor layer, wherein the third and fourth nitride-based semiconductor layers have the same composition and different physical characteristics, and the third nitride-based semiconductor layer is thinner than the fourth nitride-based semiconductor layer.

22-25. (canceled)
